(19) United States
(12) Patent Application Publication
(10) Pub. No.: US 2021/0102668 A1
(43) Pub. Date: Apr. 8, 2021

(54) LED LAMP SHEET

(71) Applicant: GUANGZHOU JUHONG OPTOELECTRONICS CO., LTD., GUANGZHOU (CN)

(72) Inventor: XILONG XIE, GUANGZHOU (CN)

(21) Appl. No.: 16/969,991

(22) PCT Filed: Apr. 29, 2019
(86) PCT No.: PCT/CN2019/084944

§ 371 Date: Aug. 14, 2020

(30) Foreign Application Priority Data
May 8, 2018 (CN) 201820684368.8

(51) Int. Cl. F21K 9/20; F21K 9/66; F21V 23/06; H01L 33/52; H01L 33/62

(52) U.S. Cl. CPC F21K 9/20; F21K 9/66; F21Y 2115/10; H01L 33/52; H01L 33/62; F21V 23/06

(57) ABSTRACT

The utility model discloses an LED lamp sheet, including: a substrate, a wafer, and a sealant, where a body of the substrate is made of a high temperature resistant insulating material, a bottom surface of the substrate is provided with a positive electrode connector and a negative electrode connector, a top surface of the substrate is provided with a first terminal electrically connected to the positive electrode connector and a second terminal electrically connected to the negative electrode connector, the wafer is electrically connected to the first terminal and the second terminal, and the sealant is double-humped. The LED lamp sheet is free of pins and has a small size and a large irradiation area, thereby facilitating commercial use of the LED lamp sheet.

### TECHNICAL FIELD

The utility model relates to the field of LED technologies, and in particular, to an LED lamp sheet.

### BACKGROUND

As a semiconductor luminescent material, an ED light source has advantages such as energy saving, environmental protection, high color rendering, and stable luminescence. Compared with other light sources, the ED light source is eco-friendly, highly efficient, reliable, and durable, and therefore will gradually replace conventional light sources. An LED street lamp is a combination of multiple high-power LED light sources, and is distributed in the form of a plane lattice. Secondary optical light distribution is performed through an external lens or a reflector cup to control the distribution range of light. The emitted light becomes a long strip of light distributed along the road to meet requirements of road lighting.

However, a current LED lamp sheet has a limited light radiation area due to a planar structure of a wafer, and needs to be used with an external reflector to implement wide-range lighting when being used as a street lamp. In addition, during packaging of the LED lamp sheet, pins need to be wired. As a result, the LED lamp sheet has a large size, and its pins may be easily broken.

### SUMMARY

To overcome the disadvantages of the prior art, the utility model is intended to provide a small-sized LED lamp sheet with a large irradiation angle.

The objective of the utility model is achieved by using the following technical solutions:

An LED lamp sheet, including: a substrate, a wafer, and a sealant, where a body of the substrate is made of a high temperature resistant insulating material, a bottom surface of the substrate is provided with a positive electrode connector and a negative electrode connector, a top surface of the substrate is provided with a first terminal electrically connected to the positive electrode connector and a second terminal electrically connected to the negative electrode connector, the wafer is electrically connected to the first terminal and the second terminal, and the sealant is double-humped.

Further, the wafer is electrically connected to the first terminal and the second terminal by using a bonding wire.

Further, the wafer is of an inverted structure and is directly electrically connected to the first terminal and the second terminal.

Further, both the positive electrode connector and the negative electrode connector are strip-shaped and disposed in parallel.

Further, both the positive electrode connector and the negative electrode connector pass through the bottom surface of the substrate.

Further, the size of the substrate is (3.5-5)×5.0 mm.

Further, the aspect ratio of the sealant is (2.8-3.0):(1.6-1.8):1.

Further, the ratio of the length of the sealant to the center distance of humps is 0.6-1.7):1.

Further, the substrate is a ceramic substrate.

Compared with the prior art, the utility model has the following beneficial effects:

The utility model provides the LED lamp sheet. The LED lamp sheet uses the insulating substrate and built-in positive electrode and negative electrode circuits that connect the bottom surface to the top surface, so that the LED lamp sheet can be free of pins, greatly reducing the size of the LED lamp sheet, improving the convenience of processing, and reducing processing costs. The LED lamp sheet is in the form of double humps, so that the length and width of the irradiation range of the LED lamp sheet increase greatly, thereby facilitating commercial use of the LED lamp sheet.

### BRIEF DESCRIPTION OF DRAWINGS

FIG. 1 is a schematic structural diagram illustrating a top view of the utility model;

FIG. 2 is a schematic structural diagram illustrating a front view of the utility model;

FIG. 3 is a schematic diagram illustrating a connection between a substrate and a wafer of the utility model;

FIG. 4 is a schematic structural diagram illustrating a bottom surface of a substrate of the utility model;

FIG. 5 is a schematic diagram illustrating a viewing angle of the utility model; and

FIG. 6 is a schematic diagram illustrating a size of the utility model.

In the drawings, the reference numerals are as follows: I. Substrate; II. Positive electrode connector; 12. Negative electrode connector; 13. First terminal; 14. Second terminal; 2. Wafer; 3. Sealant.

### DESCRIPTION OF EMBODIMENTS

The following further describes the utility model with reference to the accompanying drawings and specific embodiments. It should be noted that the following described embodiments or technical features may be randomly combined to constitute new embodiments provided that there is no conflict.

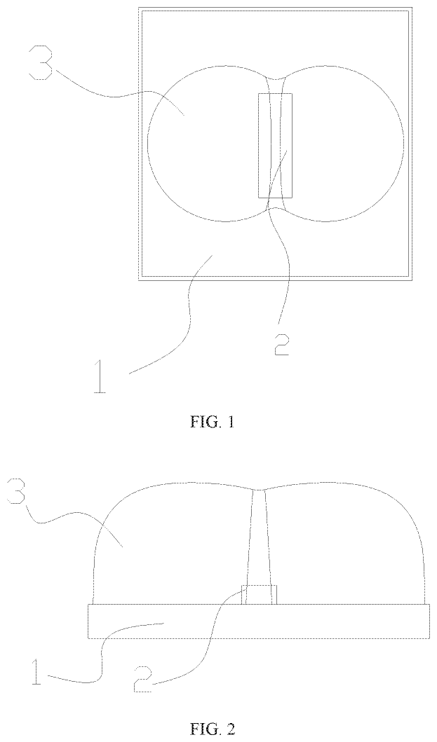

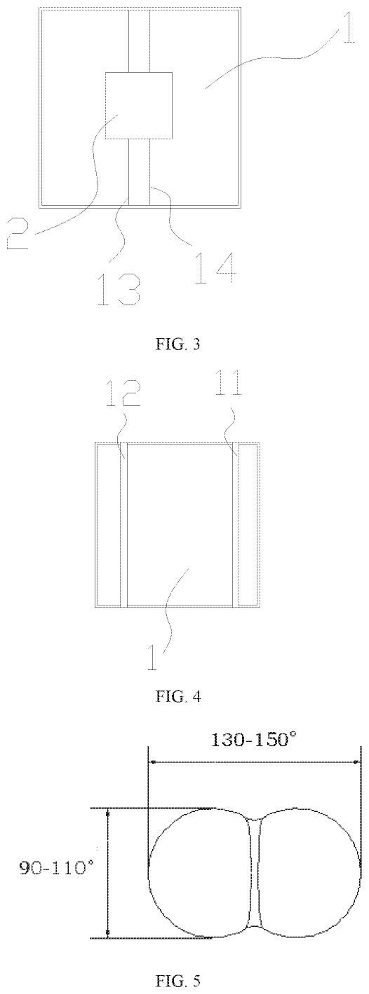

As shown in FIG. 1 and FIG. 2, an LED lamp sheet includes a substrate 1, a wafer 2, and a sealant 3. A body of the substrate 1 is made of a high temperature resistant insulating material. As shown in FIG. 3 and FIG. 4, a bottom surface of the substrate 1 is provided with a positive electrode connector 11 and a negative electrode connector 12, a top surface of the ceramic substrate 1 is provided with a first terminal 13 electrically connected to the positive electrode connector 11 and a second terminal 14 electrically connected to the negative electrode connector 12, the wafer 2 is electrically connected to the first terminal 13 and the second terminal 14, and the sealant 3 is double-humped.

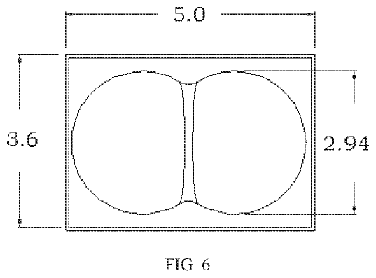

In the LED lamp sheet provided by the utility model, the irradiation area of light from the water 2 can be expanded by using the scattering effect of the double-humped sealant 3, so that the irradiation performance of the LED lamp sheet can be greatly improved. As shown in FIG. 5, the transverse viewing angle of the LED lamp sheet along double humps can reach 130-150°, which can effectively resolve the problem of a limited irradiation range in commercial lighting without the need for additional reflectors. Use of pins can be avoided by using the high temperature resistant insulating substrate 1 and a wiring circuit extending from the top surface to the bottom surface of the substrate 1, so that the LED lamp sheet has a smaller size and can be easily connected to other carriers.

The LED lamp sheet is applicable to three types of packaging structures: vertical, planar, and inverted. When the vertical or the planar packaging structure is used, the wafer 2 is fastened to the ceramic substrate 1 before a bonding wire is welded on the wafer 2, the positive electrode of the water 2 is electrically connected to the first terminal 13, and the negative electrode of the water 2 is electrically connected to the second terminal 14. When the inverted packaging structure is used, the positive electrode of the wafer 2 is directly electrically connected to the first terminal 13, and the negative electrode is directly electrically connected to the second terminal 14, so that the wire welding process can be omitted.

To ensure that the LED lamp sheet can be easily connected, both the positive electrode connector 11 and the negative electrode connector 12 are disposed in strips and parallel to each other, so that the positive electrode connector 11 and the negative electrode connector 12 can be directly used after elements are bonded, and the operation process is simpler. Further, both the positive electrode connector 11 and the negative electrode connector 12 pass through the bottom surface of the substrate 1; that is, electrical components can be engaged at both ends of the LED lamp sheet.

The substrate 1 of the LED lamp sheet is made of the high temperature resistant insulating material, and preferably has relatively high resistance to deformation. Specifically, the substrate 1 may include but is not limited to a ceramic substrate 1, a high-density polyethylene substrate 1, or a polyamine substrate 1.

The double-hump structure of the sealant 3 of the LED lamp sheet preferably satisfies the following size relationship: The aspect ratio of the sealant 3 is (2.8-3.0):(1.6-1.8):1. The ratio of the length of the sealant 3 to the center distance of the humps is (1.6-1.7):1. The sealant 3 of this size has better scattering and a better packaging function.

The size of the substrate 1 is preferably (3.5-5) mm×5.0 mm.

The longitudinal viewing angle of the LED lamp sheet can reach 90-110° and the transverse viewing angle can reach 130-150°.

FIG. 6 provides an example of the size of the LED lamp sheet: The size of the substrate 1 is 3.6 mm×5.0 mm, the dimensions of the sealant 3 are 4.9 mm×2.94 mm×2.25 mm (length×width×height), the center distance of the double humps of the sealant 3 is 1.89 mm, and the height of the sealant 3 is 1.77 mm.

The foregoing implementations are merely preferred implementations of the utility model, and are not intended to limit the protection scope of the utility model. Any non-substantive changes and replacements made by a person skilled in the art based on the utility model shall fall within the protection scope of the utility model.

What is claimed is:

1. An LED lamp sheet, comprising: a substrate, a wafer, and a sealant, wherein a body of the substrate is made of a high temperature resistant insulating material, a bottom surface of the substrate is provided with a positive electrode connector and a negative electrode connector, a top surface of the substrate is provided with a first terminal electrically connected to the positive electrode connector and a second terminal electrically connected to the negative electrode connector, the wafer is electrically connected to the first terminal and the second terminal, and the sealant is double-humped.

2. The LED lamp sheet according to claim 1, wherein the wafer is electrically connected to the first terminal and the second terminal by using a bonding wire.

3. The LED lamp sheet according to claim 1, wherein the wafer is of an inverted structure and is directly electrically connected to the first terminal and the second terminal.

4. The LED lamp sheet according to claim 1, wherein both the positive electrode connector and the negative electrode connector are strip-shaped and disposed in parallel.

5. The LED lamp sheet according to claim 1, wherein both the positive electrode connector and the negative electrode connector pass through the bottom surface of the substrate.

6. The LED lamp sheet according to claim 1, wherein the size of the substrate is (3.5-5) mm×5.0 mm.

7. The LED lamp sheet according to claim 1, wherein the aspect ratio of the sealant is (2.8-3.0):(1.6-1.8):1.

8. The LED lamp sheet according to claim 1, wherein the ratio of the length of the sealant to the center distance of humps is (1.6-1.7):1.

9. The LED lamp sheet according to claim 1, wherein the substrate is a ceramic substrate.
